(19) United States
(12) Patent Application Publication
(10) Pub. No.: US 2023/0004533 A1
(43) Pub. Date: Jan. 5, 2023

(54) HYBRID INTERMEDIATE STREAM FORMAT

(71) Applicant: Microsoft Technology Licensing, LLC, Redmond, WA (US)

(72) Inventor: Renat VALIULLIN, Redmond, WA (US)

(21) Appl. No.: 17/365,774

(22) Filed: Jul. 1, 2021

(51) Int. Cl. G06F 16/174; H03M 7/30

(52) U.S. Cl. CPC G06F 16/1744; H03M 7/3064; H03M 7/3066; H03M 7/6064

(57) ABSTRACT

Systems and methods providing a hybrid intermediate stream format are provided. The method includes compressing a vertex into a first data block via a first compression method, compressing the vertex into a second data block via a second compression method, determining a smaller file of the first data block and the second data block, finalizing compression of the vertex via a compression method, selected from the first compression method and the second compression method, corresponding to the determined smaller file of the first data block and the second data block, and transferring the compressed vertex.

### BACKGROUND

Data is stored in vertices comprising numerous rows and columns. Transferring the data stored in a vertex is accomplished by transferring the data column-by-column and row-by-row using temporary storage, such as a disc. To reduce the time and resources required to transfer the data stored in the vertex, the data can be compressed. However, due to the different methods of compressing data contained in a vertex, at times an inefficient method of compressing the data can be executed, leading to wasted time and resources.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Examples and implementations disclosed herein are directed to systems and methods that provide a hybrid intermediate stream format. The method includes compressing a vertex into a first data block via a first compression method, compressing the vertex into a second data block via a second compression method, determining a smaller file of the first data block and the second data block, finalizing compression of the vertex via a compression method, selected from the first compression method and the second compression method, corresponding to the determined smaller file of the first data block and the second data block, and transferring the compressed vertex.

### BRIEF DESCRIPTION OF THE DRAWINGS

The present description will be better understood from the following detailed description read in light of the accompanying drawings, wherein:

FIG. 1 is a block diagram illustrating an example computing device for implementing various examples of the present disclosure;

FIG. 2 is a block diagram illustrating a fragment of a simple scope job according to examples of the present disclosure;

FIG. 3 is a block diagram illustrating an example vertex of data according to examples of the present disclosure;

FIG. 4 is a block diagram illustrating a sequence of single row blocks according to examples of the present disclosure;

FIG. 5 is a block diagram illustrating an intermediate buffer according to examples of the present disclosure;

FIG. 6 is a block diagram illustrating a column chunk block according to examples of the present disclosure;

FIG. 7 is a computerized method for writing a row to an intermediate buffer according to examples of the present disclosure;

FIG. 8 is a computerized method for flushing the intermediate buffer according to examples of the present disclosure;

FIG. 9 is a computerized method for generating block type 0/column chunk block according to examples of the present disclosure;

FIG. 10 is a computerized method for generating block type 1/row in v1 format according to examples of the present disclosure; and

FIG. 11 is a computerized method for compressing and transferring data according to examples of the present disclosure.

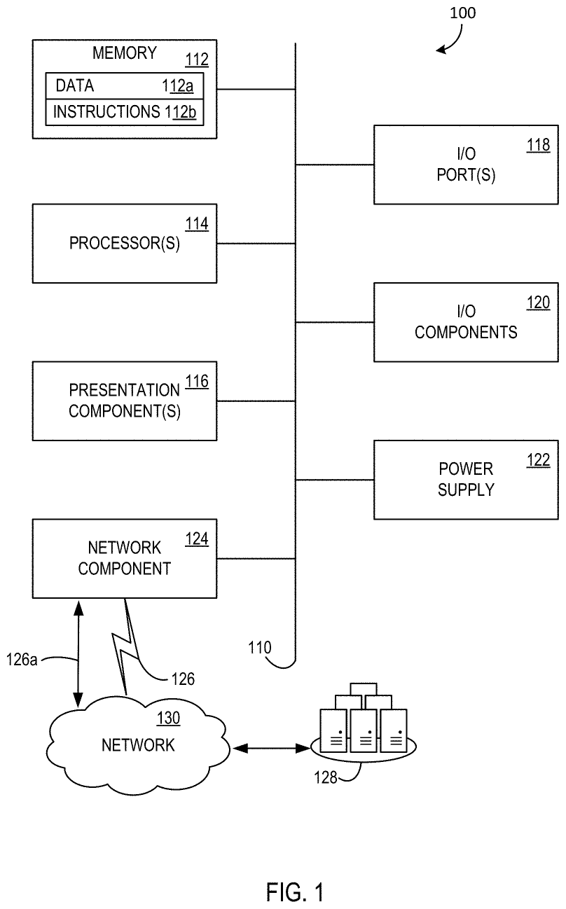

Corresponding reference characters indicate corresponding parts throughout the drawings. In FIGS. 1 to 11, the systems are illustrated as schematic drawings. The drawings may not be to scale.

### DETAILED DESCRIPTION

The various implementations and examples will be described in detail with reference to the accompanying drawings. Wherever possible, the same reference numbers will be used throughout the drawings to refer to the same or like parts. References made throughout this disclosure relating to specific examples and implementations are provided solely for illustrative purposes but, unless indicated to the contrary, are not meant to limit all examples.

As described above, conventional methods of transferring the data stored in a vertex is accomplished by transferring the data column-by-column and row-by-row using temporary storage. Various compression methods are available to make the transfer process more efficient, i.e., utilize less time and less resources. For example, the vertex is compressed into a smaller file size to be transferred, which requires less memory space to complete the data transfer.

Memory space for transferring data in instances where a stream has a hard limit for required memory. When transferring data, an intermediate stream can be used to transfer data between execution nodes in large data processing job, such as Cosmos/ADL analytics. For example, one or more data inputs are input into an execution node which outputs one or more data outputs. The intermediate stream is conventionally implemented as a stream in a compressed data structure format that includes rows and columns of data and works using double buffering. Because an execution node can have several input or output streams, such as in the case of a joiner or a splitter, an outputter or extractor for a stream can have a hard limit for the required memory.

However, current solutions fail to accurately identify the most efficient compression method. In particular, due to the differences in compression methods, some methods can improve the efficiency of transferring particular data or types of data more than other methods. For example, data stored in rows and columns can be compressed and transferred either row-by-row or column-by-column. However, whether row-by-row or column-by-column is the more efficient method of compression and transfer can depend on the data itself. Current solutions fail to effectively determine which type of compression and transfer is more efficient, taking into account the speed of the compression and transfer, the amount of resources, such as memory, required for the compression and transfer, and so forth.

Various examples of the present disclosure address the above-identified challenges by analyzing the data to be compressed and transferred and, based on the analysis, determining the most efficient method of compression. For example, the data included in a vertex can be compressed into an intermediate stream using both a row-by-row method and a column-by-column method. A codec is executed to estimate a size of each data block resulting from the intermediate streams of both the row-by-row and column-by-column methods of compression. Based at least in part on the results of the estimation by the codec, the more cost-effective data block resulting from compression is selected to complete the data transfer from an intermediate stream to a single row data block, which is then transmitted to the new data location.

Aspects of the present disclosure provide a computer-implemented method and system for a hybrid intermediate stream format. The method includes compressing a vertex into a first data block via a first compression method, compressing the vertex into a second data block via a second compression method, determining a smaller file of the first data block and the second data block, finalizing compression of the vertex via a compression method, selected from the first compression method and the second compression method, corresponding to the determined smaller file of the first data block and the second data block, and transferring the compressed vertex.

Accordingly, the system provided in the present disclosure operates in an unconventional manner by selecting a compression method for compressing and transferring data based on an intermediate stream of the data to be transferred. In particular, compressing a vertex into two different intermediate streams, generated by different methods of compression, in order to estimate a cost for transferring the data improves the compression ratio, utilizes limited memory usage, and utilizes relatively little memory and CPU overhead compared to previous solutions. More specifically, the examples provided herein enable a preliminary determination to be made without utilizing additional resources to fully compress the data via either method. Further, the selection of a compression method is made based on the intermediate stream generated by the initial compression, rather than based on external factors.

FIG. 1 is a block diagram illustrating an example computing device 100 for implementing aspects disclosed herein and is designated generally as computing device 100. Computing device 100 is but one example of a suitable computing environment and is not intended to suggest any limitation as to the scope of use or functionality of the examples disclosed herein. Neither should the computing device 100 be interpreted as having any dependency or requirement relating to any one or combination of components/modules illustrated.

The examples disclosed herein may be described in the general context of computer code or machine- or computer-executable instructions, such as program components, being executed by a computer or other machine. Program components include routines, programs, objects, components, data structures, and the like that refer to code, performs particular tasks, or implement particular abstract data types. The disclosed examples may be practiced in a variety of system configurations, including servers, personal computers, laptops, smart phones, servers, VMs, mobile tablets, hand-held devices, consumer electronics, specialty computing devices, etc. The disclosed examples may also be practiced in distributed computing environments when tasks are performed by remote-processing devices that are linked through a communications network.

The computing device 100 includes a bus 110 that directly or indirectly couples the following devices: computer-storage memory 112, one or more processors 114, one or more presentation components 116, I/O ports 118, I/O components 120, a power supply 122, and a network component 124. While the computing device 100 is depicted as a seemingly single device, multiple computing devices 100 may work together and share the depicted device resources. For example, memory 112 is distributed across multiple devices, and processor(s) 114 is housed with different devices. Bus 110 represents what may be one or more busses (such as an address bus, data bus, or a combination thereof). Although the various blocks of FIG. 1 are shown with lines for the sake of clarity, delineating various components may be accomplished with alternative representations. For example, a presentation component such as a display device is an I/O component in some examples, and some examples of processors have their own memory. Distinction is not made between such categories as “workstation,” “server,” “laptop,” “hand-held device,” etc., as all are contemplated within the scope of FIG. 1 and the references herein to a “computing device.”

Memory 112 may take the form of the computer-storage memory device referenced below and operatively provide storage of computer-readable instructions, data structures, program modules and other data for the computing device 100. In some examples, memory 112 stores one or more of an operating system (OS), a universal application platform, or other program modules and program data. Memory 112 is thus able to store and access data 112a and instructions 112b that are executable by processor 114 and configured to carry out the various operations disclosed herein. In some examples, memory 112 stores executable computer instructions for an OS and various software applications. The OS may be any OS designed to the control the functionality of the computing device 100, including, for example but without limitation: WINDOWS® developed by the MICROSOFT CORPORATION®, MAC OS® developed by APPLE, INC.® of Cupertino, Calif., ANDROID™ developed by GOOGLE, INC.® of Mountain View, Calif., open-source LINUX®, and the like.

By way of example and not limitation, computer readable media comprise computer-storage memory devices and communication media. Computer-storage memory devices may include volatile, nonvolatile, removable, non-removable, or other memory implemented in any method or technology for storage of information such as computer-readable instructions, data structures, program modules, or the like. Computer-storage memory devices are tangible and mutually exclusive to communication media. Computer-storage memory devices are implemented in hardware and exclude carrier waves and propagated signals. Computer-storage memory devices for purposes of this disclosure are not signals per se. Example computer-storage memory devices include hard disks, flash drives, solid state memory, phase change random-access memory (PRAM), static random-access memory (SRAM), dynamic random-access memory (DRAM), other types of random-access memory (RAM), read-only memory (ROM), electrically erasable programmable read-only memory (EEPROM), flash memory or other memory technology, compact disk read-only memory (CD-ROM), digital versatile disks (DVD) or other optical storage, magnetic cassettes, magnetic tape, magnetic disk storage or other magnetic storage devices, or any other non-transmission medium that may be used to store information for access by a computing device. In contrast, communication media typically embody computer readable instructions, data structures, program modules, or the like in a modulated data signal such as a carrier wave or other transport mechanism and include any information delivery media.

The computer-executable instructions may be organized into one or more computer-executable components or modules. Generally, program modules include, but are not limited to, routines, programs, objects, components, and data structures that perform particular tasks or implement particular abstract data types. Aspects of the disclosure may be implemented with any number an organization of such components or modules. For example, aspects of the disclosure are not limited to the specific computer-executable instructions or the specific components or modules illustrated in the figures and described herein. Other examples of the disclosure may include different computer-executable instructions or components having more or less functionality than illustrated and described herein. In examples involving a general-purpose computer, aspects of the disclosure transform the general-purpose computer into a special-purpose computing device, CPU, GPU, ASIC, system on chip (SoC), or the like for provisioning new VMs when configured to execute the instructions described herein.

Processor(s) 114 may include any quantity of processing units that read data from various entities, such as memory 112 or I/O components 120. Specifically, processor(s) 114 are programmed to execute computer-executable instructions for implementing aspects of the disclosure. The instructions may be performed by the processor 114, by multiple processors 114 within the computing device 100, or by a processor external to the client computing device 100. In some examples, the processor(s) 114 are programmed to execute instructions such as those illustrated in the flow charts discussed below and depicted in the accompanying figures. Moreover, in some examples, the processor(s) 114 represent an implementation of analog techniques to perform the operations described herein. For example, the operations are performed by an analog client computing device 100 and/or a digital client computing device 100.

Presentation component(s) 116 present data indications to a user or other device. Example presentation components include a display device, speaker, printing component, vibrating component, etc. One skilled in the art will understand and appreciate that computer data may be presented in a number of ways, such as visually in a graphical user interface (GUI), audibly through speakers, wirelessly between computing devices 100, across a wired connection, or in other ways. I/O ports 118 allow computing device 100 to be logically coupled to other devices including I/O components 120, some of which may be built in. Example I/O components 120 include, for example but without limitation, a microphone, joystick, game pad, satellite dish, scanner, printer, wireless device, etc.

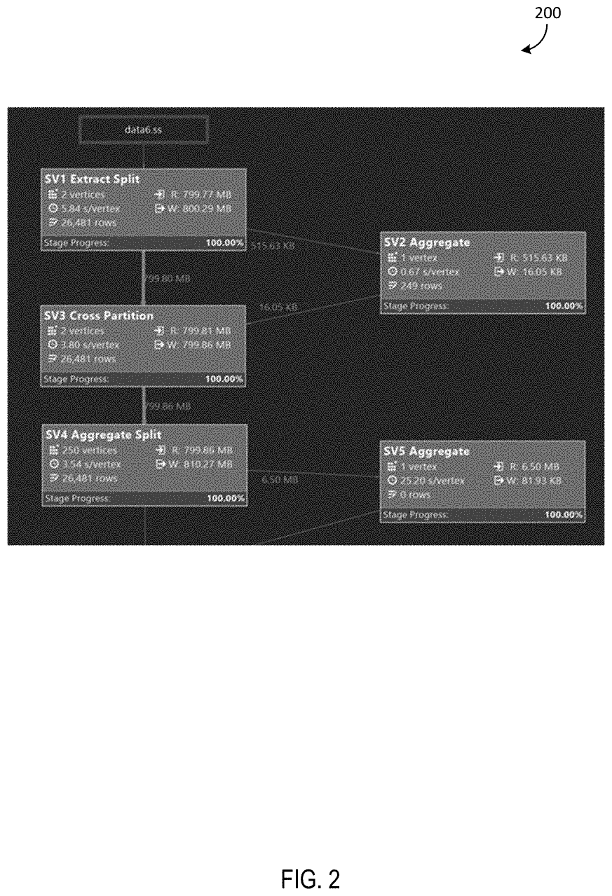

The computing device 100 may communicate over a network 130 via network component 124 using logical connections to one or more remote computers. In some examples, the network component 124 includes a network interface card and/or computer-executable instructions (e.g., a driver) for operating the network interface card. Communication between the computing device 100 and other devices may occur using any protocol or mechanism over any wired or wireless connection. In some examples, network component 124 is operable to communicate data over public, private, or hybrid (public and private) using a transfer protocol, between devices wirelessly using short range communication technologies (e.g., near-field communication (NFC), Bluetooth™ branded communications, or the like), or a combination thereof. Network component 124 communicates over wireless communication link 126 and/or a wired communication link 126a across network 130 to a cloud environment 128, such as one or more of the cloud-computing environments depicted in FIGS. 2-10. Various different examples of communication links 126 and 126a include a wireless connection, a wired connection, and/or a dedicated link, and in some examples, at least a portion is routed through the Internet.

The network 130 may include any computer network or combination thereof. Examples of computer networks configurable to operate as network 130 include, without limitation, a wireless network; landline; cable line; digital subscriber line (DSL): fiber-optic line; cellular network (e.g., 3G, 4G, 5G, etc.); local area network (LAN); wide area network (WAN); metropolitan area network (MAN); or the like. The network 130 is not limited, however, to connections coupling separate computer units. Rather, the network 130 may also include subsystems that transfer data between servers or computing devices. For example, the network 130 may also include a point-to-point connection, the Internet, an Ethernet, an electrical bus, a neural network, or other internal system. Such networking architectures are well known and need not be discussed at depth herein.

In some examples, the computing device 100 compresses data and transfers the compresses data to another device. For example, the computing device 100 compresses data and transfers the compressed data to a vertex stored by the cloud environment 128 via the network 130. However, various examples are possible. The computing device 100 can transfer the data to an external computing device or store the compressed data for future transfer without departing from the scope of the present disclosure. Furthermore, the present disclosure contemplates various examples of compressing data for transfer, based at least in part on the format of the original data and the format of the data received by the cloud environment.

In one particular example, the computing device 100 receives a data packet. The processor 114 extracts data from the packet and converts the data into a vertex comprising rows and columns. In some examples, the extracted data from the packet is in binary form. In other words, the data is provided within the vertex as a 0, 1, or null. An example vertex including one row and five columns is provided in Table 1 below.

TABLE 1

| | Column 1 | Column 2 | Column 3 | Column 4 | Column 5 |
|---|---|---|---|---|---|
| Row 1 | Null | 0 | 1 | 1 | Null |

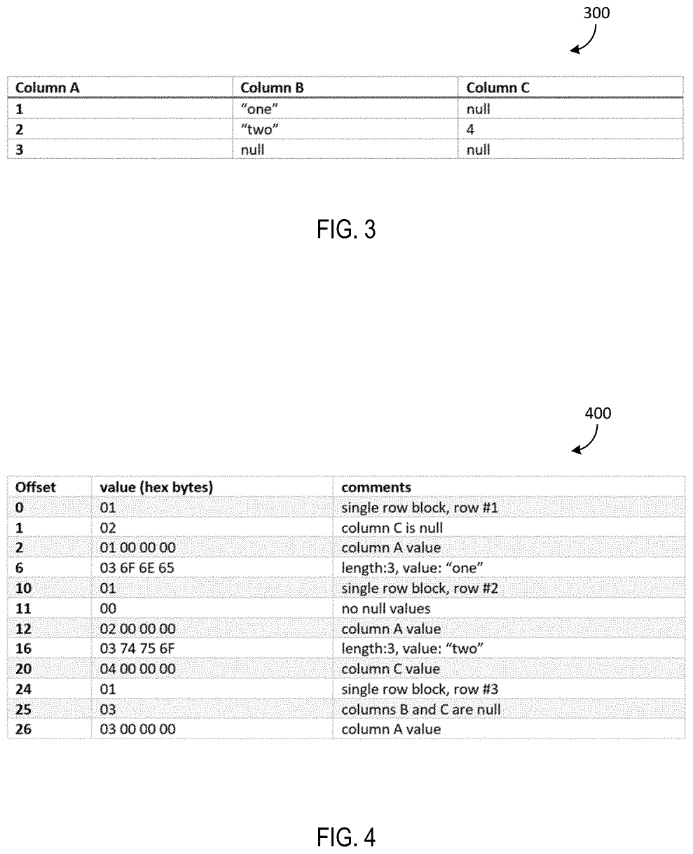

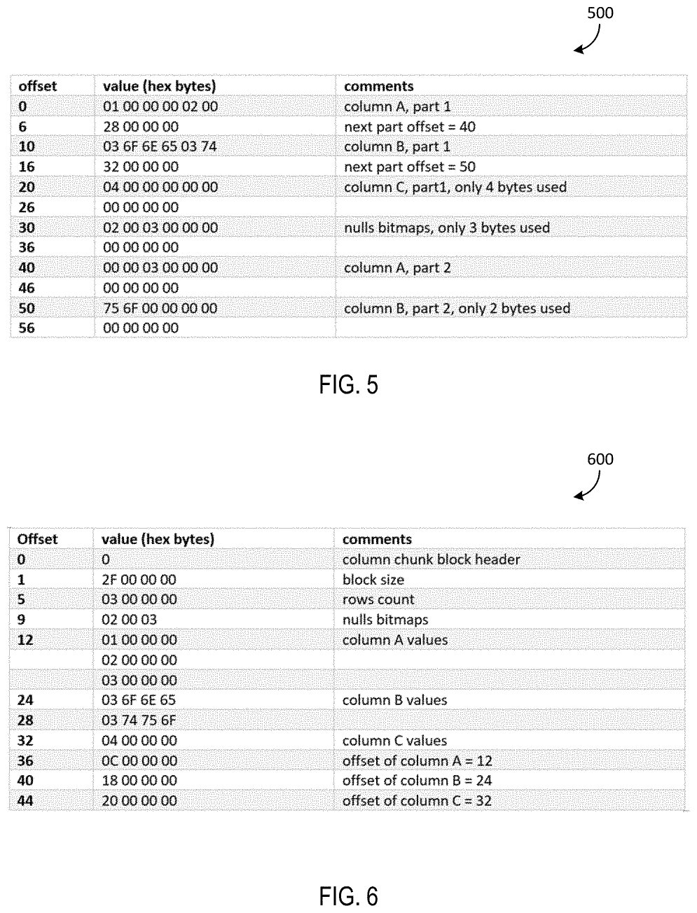

A vertex, for example but not limited to the vertex illustrated in Table 1, can be serialized into a buffer stream using at least two different methods, row-by-row serialization and column chunk serialization. For example, as illustrated in FIG. 3 below, row-by-row serialization results in a stream, such as [row0.column0 . . . row0.columnK] [row1.column0 . . . row1.columnK] and so forth until each row has been serialized. As another example, as illustrated in FIG. 5 below, column chunk serialization results in a stream, such as [row0.column0 . . . rowN.column0] [row0.column1 . . . rowN.column1] and so forth until each column chunk has been serialized. Row-by-row serialization and column chunk serialization each have advantages and disadvantages as methods for compressing and transferring the data extracted from the packet.

The column-chunk format typically compresses data into a smaller file size because same kind values are typically grouped together. Accordingly, compressing data into a smaller file size can be advantageous when transferring the file. However, column-chunk format is less flexible and more expensive. Each chunk utilizes its own buffer, leading to an increase in memory usage to write the file. For example, each row block is in the memory and has a recommended size for widespread parquet/orc. Hundreds of Mb can be required to sufficiently work with a large number of columns and rows. Similarly, the same size buffer is typically required for reading. The row-by-row format enables column values to be written and/or read one-by-one using only a fixed size IO buffer.

Accordingly, examples of the present disclosure provide an intermediate stream format with an improved compression ratio, in some examples several times better, when compared to row-by-row formats, limited memory usage of approximately an IO buffer size, and relatively low memory and CPU overhead requirements. Memory usage can be limited even for rows that contain data numbering in the hundreds of Mb. The stream format is provided as [magic number: “BIN2”] [data block] . . . [data block]. The data block can refer to either a single row data block or a column-chunk block.

A single row data block is provided as [byte: 1] [nulls bitmap] [column0 . . . columnK]. In a single row data block, null values are skipped and not included, but the corresponding bit is set in nulls bitmap. The variable size values (string/binaries) prepends using prefix (uleb128) encoded size. A column-chunk block is provided as [byte: 0, unit 32 block-size, rows count] [nulls bitmaps] [column-chunks] [columns offsets table]. In the column-chunk block, nulls bitmap and column values are serialized in the same manner as the single row block but are instead grouped into column-chunks. Column 0 to column K represent all serialized non-null values in the particular columns while compressing out the null values.

As referenced herein, a block size refers to a size, expressed in bytes, of the data block. In other words, the block size determines the amount of data in the data block. Nulls bitmap refers to how much data is included in a data block. For example, Table 1 illustrates five columns, two of which are null values and three of which are non-null values. Accordingly, the nulls bitmap value for Table 1 is three. The byte value of Table 1 is 1, because the data block has one row. Columns-chunk refers to the data included in the particular column or row. The columns offset table is offset to the start of each column chunk table. For example, if there are two columns in the vertex, the columns offset table contains two values.

Accordingly, various examples of the present disclosure provide an improved intermediate schema. For example, the computing device 101 skips the nulls bitmap block where the stream schema contains only non-nullable columns. In another example, nulls bitmap is compacted for rows without nulls using an extra bit in the bitmap. In yet another example, schema is sorted by column types, to group same type values, that provides at least a 0.5% gain over real data.

In some examples, the computing device 101 converts the data to the intermediate format. As the computing device 101 writes a row into the intermediate stream, the outputter estimates the size of the row and ignores the nulls. In examples where the row size exceeds the rest of the intermediate buffer, the buffer is flushed. In examples where the row size exceeds the buffer size, the row size is written as a single-row data block. In examples where the computing device 101 determines the buffer includes sufficient space for the corresponding column chunks, the column values and nulls bitmap are written into the corresponding column chunks. In some examples, the computing device implements an intermediate buffer as an auto-resizable buffer as [column0.chunk0] . . . [columnK.chunk0] [nulls.chunk0]. For example, the auto-resizable buffer is reserved virtual space including maximum possible overhead. As referenced herein, column chunk refers to fixed size data and four bytes that are offset to the next chunk, or zero if the last.

In examples where the column chunk is full, a new chunk, of the same size, is allocated at the end of the buffer. In some examples, the physical memory page may be committed at that time. In some examples, data size for fixed size columns, for example numeric types, bool, char, and so forth, is 128 multiplied by the size of the type. Accordingly, 2 Kb can be the maximum data size for fixed size columns. In some examples, the data size for variable size columns, for example string and binary columns, can be 2 Kb. Therefore, the maximum memory overhead is approximately 1 Mb where the maximum column count in a row is limited by 512. For example, 512 columns multiplied by 2 Kb maximum data size provides approximately 1 Mb.

In some examples, the computing device 101 generates a flush buffer. In some examples, the intermediate buffer is converted to the final column store block format with minimal complexity, such as via a memcpy function. For example, the conversion from the intermediate buffer illustrated in FIG. 4 to the final intermediate block illustrated in FIG. 5 is executed by copying an amount of bytes in the column-chunk format one by one. In examples where the buffer holds only one row, the buffer is serialized as a single-row data block. In other words, a header and/or tail is not needed for where the buffer holds only one row.

In some examples, the column-chunk format can output less desirable results following compression. In this example, the compression of the first data block can be estimated in both row-by-row and column-chunk formats to determine which is more cost-effective and use that particular format to finish the compression and transfer. In one example, a first data block of the stream, which includes approximately 4 MB of data, is stored in an intermediate buffer, as illustrated in FIG. 4 below. The first data block is converted into both the row-by-row format and the column-chunk format. As described below, FIG. 3 illustrates the sequence of 1 row blocks, i.e., a V1 block, and FIG. 5 illustrates a column-chunk block, i.e., a V0 block. The generated row-by-row blocks and the column-chunk blocks are compressed. The respective sizes of the blocks in the row-by-row format and the column chunk format are compared to determine the smaller size. The format that is determined to be smaller is then used for the rest of the stream.

In some examples, the computing device 101 reads the block header to determine the size of the compressed block rather than reading the data itself. For example, if a block is a single row, column values are read one by one. Column stored blocks are read into the buffer completely, column iterators are initialized using the offsets table, and the values are read from the buffer with respect to the nulls bitmaps.

FIG. 2 is a block diagram illustrating a fragment of a simple scope job according to examples of the present disclosure. The block diagram 200 illustrated in FIG. 2 is provided for illustration only. Other examples of the block diagram 200 can be used without departing from the scope of the present disclosure. It should be understood that the example data included in FIG. 2 is for illustration only and should not be construed as limiting. Various examples of number of vertices, size of rows, time to read, and amounts of data read and written are possible without departing from the scope of the present disclosure.

As shown in FIG. 2, SV1, SV2, SV3, SV4, and SV5 are respective stages of the simple scope job. In SV1, input data is read. In other words, in SV1, data is extracted, such as from external storage. The extracted data can include two partitions, one input and one output for each vertex. In SV1 illustrated in FIG. 2, the input data includes two vertices, 26,481 rows, the input data was read in 5.84 seconds/vertex, 799.77 MB of data was read, and 800.29 MB of data was written. In SV2, the input data is aggregated, i.e., compressed, into one vertex that includes 249 rows in 0.67 seconds/vertex. In SV3, the data is split into two vertices according to a new partition schema that includes one input and 250 outputs for each vertex. The new partition schema includes 26, 481 rows. In SV4, an aggregate split is performed to join the data from both initial partitions. In other words, SV4 has 2 inputs that are joined into a single output. In SV5, the output of SV4 is aggregated into one vertex.

It should be appreciated that the data illustrated in FIG. 2 is significantly compressed from SV1 to SV5. For example, SV1 reads 799.77 MB of data and writes 800.29 MB of data. In contrast, by the SV5 stage, only 6.50 MB of data is read and 81.93 KB is written.

FIG. 3 is a block diagram illustrating an example vertex of data according to examples of the present disclosure. The vertex 300 is provided for illustration only. Other examples of the vertex 300 can be used without departing from the scope of the present disclosure. As shown in FIG. 3, the vertex 300 includes three columns, Column A, Column B, and Column C, and three rows. As described herein, the nulls bitmap size for the vertex 300 is 2 bits. Column B—bit 0 and Column C—bit #1. The bitmap size of the vertex 300 is aligned to 1 byte in order to simplify encoding.

FIG. 4 is a block diagram illustrating a sequence of single row blocks according to examples of the present disclosure. The single row block 400 is provided for illustration only. Other examples of the single row block 400 can be used without departing from the scope of the present disclosure. The single row block 400 is generated from the vertex 300 illustrated in FIG. 3. Generating a single row block such as the single row block 400 has the advantage of requiring minimal memory overhead. For example, the single row block 400 can be generated even if some column values exceed the buffer size.

FIG. 5 is a block diagram illustrating an intermediate buffer according to examples of the present disclosure. The intermediate buffer 500 is provided for illustration only. Other examples of the intermediate buffer 500 can be used without departing from the scope of the present disclosure. The intermediate buffer 500 illustrated in FIG. 5 is generated from the vertex 300. The intermediate buffer 500 accumulates data utilizing a relatively small memory overhead and simplifies conversion of the data to a column chunk block, for example the column chunk block 600 illustrated in FIG. 6. The intermediate buffer 500 has a part size of six bytes, with an actual size of 2 Kb.

FIG. 6 is a block diagram illustrating a column chunk block according to examples of the present disclosure. The column chunk block 600 is provided for illustration only. Other examples of the column chunk block 600 can be used without departing from the scope of the present disclosure. The column chunk block 600 is generated from the intermediate buffer 500 illustrated in FIG. 5. In some examples, the column chunk block 600 provides improved compression over the single row block 400, but is only able to store rows smaller than the size of the block.

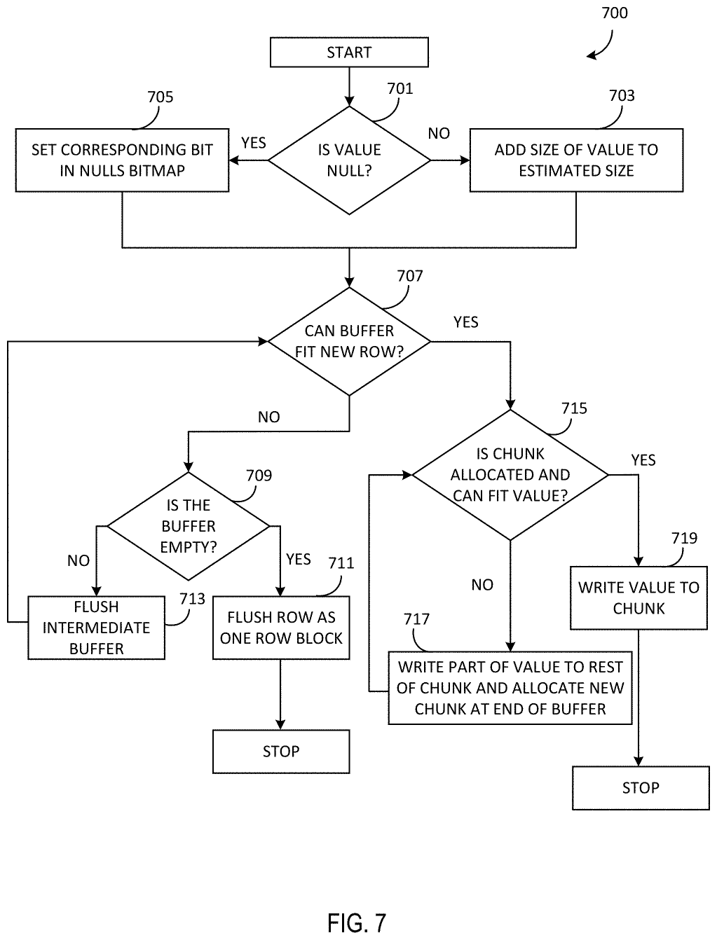

FIG. 7 is a computerized method for writing a row to an intermediate buffer according to examples of the present disclosure. The method 700 is provided for illustration only. Other examples of the method 700 can be used without departing from the scope of the present disclosure. In some examples, the method 700 can be implemented by the computing device 100.

The method 700 begins by the computing device 100 determining whether a value in a vertex of data is null in operation 701. Where a value is determined not to be null, in operation 703 the computing device 100 adds a size of the value to the estimated size of the vertex. Where a value is determined to be null, in operation 705, the computing device 100 sets a corresponding bit in the nulls bitmap.

In operation 707, the computing device 100 determines whether an intermediate buffer can fit a new row. In some examples, determining whether the intermediate buffer can fit a new row includes determining whether the intermediate buffer has sufficient space available to store a new row of data. In examples where the computing device 100 determines an intermediate buffer cannot fit a new row, the computing device 100 proceeds to operation 709. In examples where the computing device 100 determines an intermediate buffer can fit a new row, the computing device 100 proceeds to operation 715.

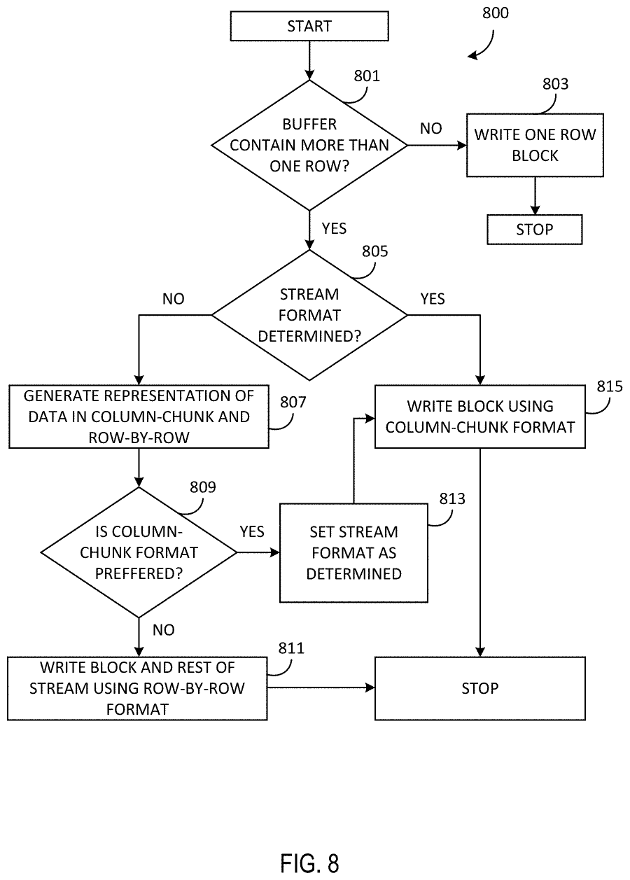

In operation 709, based on determining the buffer cannot fit a new row, the computing device 100 determines whether the buffer is empty. In examples where the computing device 100 determines the buffer is empty, in operation 711 the computing device 100 flushes the row as a one row block. In examples where the computing device 100 determines the buffer is not empty, in operation 713 the computing device 100 flushes the intermediate buffer. The process of flushing the intermediate buffer is described in greater detail below in the description of FIG. 8. Following the flushing of the intermediate buffer in operation 713, the computing device 100 returns to operation 707 and determines whether the buffer can fit a new row.

Based on a determination that the buffer cannot fit a new row in operation 707, in operation 715 the computing device 100 determines, for each non-null column value and nulls bitmap, whether a chunk is allocated and can fit the particular non-null column value. In examples where a particular chunk is not allocated and/or cannot fit the value, in operation 717 the computing device 100 writes part of the value to the rest of the chunk and allocates a new chunk at the end of the buffer. The computing device 100 then returns to operation 715 and repeats the determination of whether a chunk is allocated and can fit the particular non-null column value for the next non-null column value and nulls bitmap. In examples where, in operation 715, the computing device 100 determines the chunk is allocated and can fit the value, in operation 717 the computing device 100 writes the value to the chunk.

FIG. 8 is a computerized method for flushing the intermediate buffer according to examples of the present disclosure. The method 800 is provided for illustration only. Other examples of the method 800 can be used without departing from the scope of the present disclosure. In some examples, the method 800 can be implemented by the computing device 100. In some examples, the method 800 for flushing the intermediate buffer is an example of flushing the buffer previously described in operation 713 of the method 700.

The method 800 begins by the computing device 100 determining whether the buffer. i.e., the intermediate buffer, contains more than one row in operation 801. In examples where the computing device 100 determines the buffer does not contain more than one row, in operation 803 the computing device 100 writes the one row block. In examples where the computing device 100 determines the buffer does contain more than one row, in operation 805 the computing device 100 determines where the stream format to be used is determined. Various examples described herein recognize and take into account that, in many instances, column-chunk format is a default stream format. Accordingly, in examples where, in operation 805, the computing device 100 determines the stream format to be used is determined to use the default, column-chunk format, the computing device 100 proceeds to operation 815.

In examples where, in operation 805, the computing device 100 does not determine the stream format to be used is determined, in operation 807 the computing device 100 generates a representation of data in the column-chunk format and row-by-row format. For example, as described herein, to generate the representation of the data, the computing device 100 compresses generated row-by-row blocks and generated column-chunk blocks including headers for respective blocks.

In operation 809, the computing device 100 determines whether column-chunk format is preferred. In some examples, determining whether the column-chunk format or the row-by-row format is preferred includes determines which format is more cost-effective. Whether a method is cost-effective can be determined based on memory usage, CPU usage, and so forth required to compress and transfer the data. In examples where the column-chunk format is not determined to be preferred, i.e., the row-by-row format is preferred, in operation 811 the computing device 100 writes the block and the rest of the stream, and completes the transfer, by utilizing the row-by-row format. In examples where the column-chunk format is determined to be preferred, in operation 813 the computing device 100 sets the stream format as determined. For example, by setting the stream format as determined, the computing device 100 can determine, in a future iteration of operation 805, that column-chunk is the preferred format and save time and computing resources by avoiding additional analysis.

In operation 815, the computing device 100 writes the block using the column-chunk format. As illustrated in FIG. 8, in some examples, the computing device 100 writes the block using the column-chunk format based on the stream format being determined in operation 805 and in some examples, the computing device 100 writes the block using the column-chunk format based on the column-chunk format being determined to be the preferred format. In some examples, the transfer is completing by transferring data from the intermediate data format to an external format for long-term storage, such as a data unit or partition stream, to provide gains in compressed and non-compressed form.

Accordingly, various examples of the present disclosure utilizes an intermediate data format to provide temporary storage between vertices during vertex execution using smaller page 4 MB blocks. The present disclosure further provides a new binary format in order to write offsets in front of pages without reversing 250 MB buffer for strings. The new binary format is adaptive and is capable of switching between long row data representation and short row data representation. The new binary format holds small row data in the intermediate data format while the long data is stored in a traditional binary format. Accordingly, data can be transferred, or flushed, into the disk as the data is consumed, such as the implementation of the binary writer we have today. This reduces memory pressure while leaving all the advantages of the columnar store for intermediate vertex data storage.

In some examples, the CPU utilization of the new intermediate block writer is smaller than structured stream formats designed for permanent storage. It should be understood that various examples described herein will not require an index or data key predicate manipulation. In some examples, the stream metadata and/or tail are omitted.

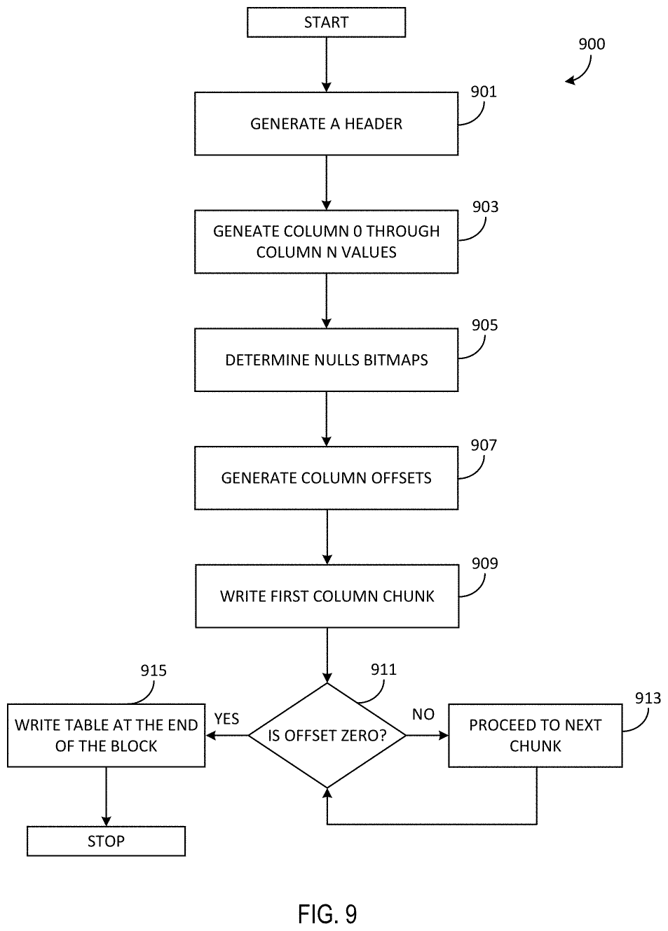

FIG. 9 is a computerized method for generating column chunk block according to examples of the present disclosure. The method 900 is provided for illustration only. Other examples of the method 900 can be used without departing from the scope of the present disclosure. In some examples, the method 900 can be implemented by the computing device 100. In some examples, the column chunk block is referred to as a block type 0.

The method 900 begins by the computing device 100 generating a header in operation 901. The header includes the size of the block and the number of rows in the block. The block size and number of rows are calculated when the rows are accumulated in the intermediate buffer. In operation 903, the computing device 100 generates the column values. The column values span from column0, the first column, to columnN, which represents the last column. The block can include any suitable number of columns without departing from the scope of the present disclosure. In operation 905, the computing device 100 determines the nulls bitmaps for the block. As described herein, nulls bitmap refers to how much data is included in a data block. In operation 907, the computing device 100 generates column offsets. As described herein, the columns offset table is offset to the start of each column chunk table. For example, if there are two columns in the vertex, the columns offset table value is two.

In operation 909, the computing device writes the first column chunk. In operation 911, the computing device 100 determines whether the offset of the written first column chunk is zero. In examples where the offset is not zero, in operation 913 the computing device 100 proceeds to write the next chunk and returns to operation 911 to determine whether the offset is zero. The loop created by operations 911 and 913 continues until, in operation 911, the computing device 100 determines the offset is zero. Based on the offset being determined to be zero, in operation 915, the computing device 100 writes the table at the end of the block.

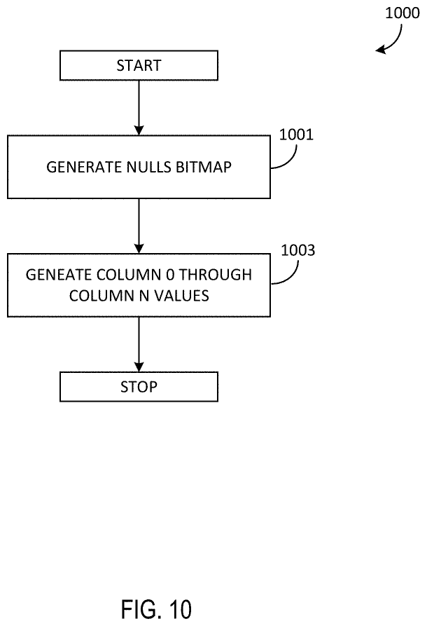

FIG. 10 is a computerized method for generating block type 1/row in v1 format according to examples of the present disclosure. The method 1000 is provided for illustration only. Other examples of the method 1000 can be used without departing from the scope of the present disclosure. In some examples, the method 1000 can be implemented by the computing device 100.

The method 1000 begins by the computing device 100 generating a nulls bitmap for the row in operation 1001. As described herein, nulls bitmap refers to how much data is included in a data block. In some examples, the nulls bitmap is calculated and written first, i.e., prior to the data of a column being available, in order for the computing device 100 to determine whether the actual value is present or null. In operation 1003, the computing device 100 generates column values for column0 through columnN. The column values span from column0, the first column, to columnN, which represents the last column.

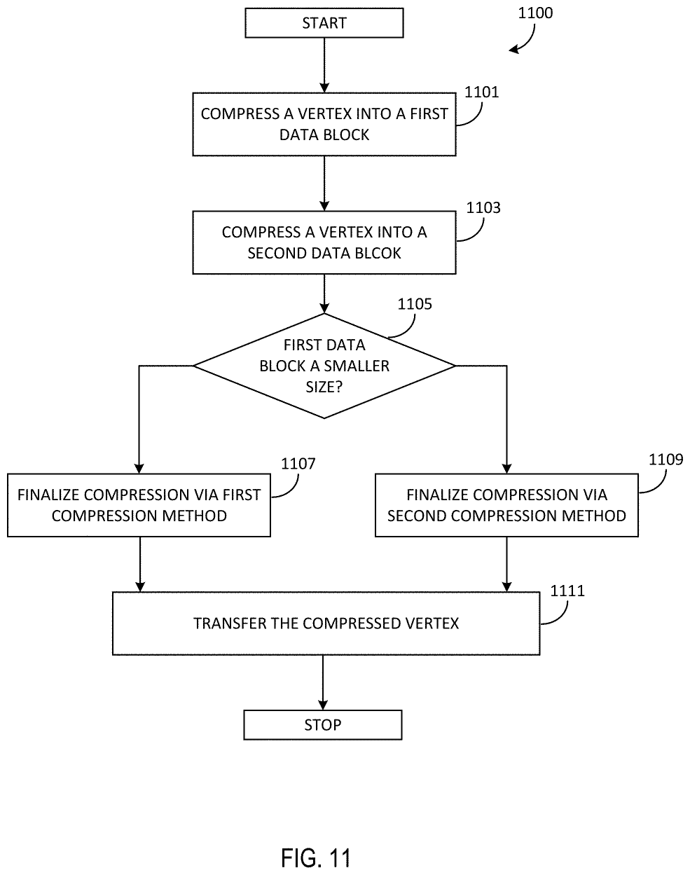

FIG. 11 is a computerized method for compressing and transferring data according to examples of the present disclosure. The method 1100 is provided for illustration only. Other examples of the method 1100 can be used without departing from the scope of the present disclosure. In some examples, the method 1100 can be implemented by the computing device 100.

The method begins by the computing device 100 compressing a vertex into a first data block via a first compression method in operation 1101. In some examples, the first compression method is a column-chunk compression format as described herein. In operation 1103, the computing device 100 compresses the vertex into a second data block via a second compression method. In some examples, the second compression method is a row-by-row compression format as described herein.

In operation 1105, the computing device 100 determines a smaller file of the first data block and the second data block. For example, each of the first data block and the second data block include a header. In other words, the first data block includes a first header and the second data block includes a second header. Each header includes the size of the respective block and the number of rows in the respective block. The computing device 100 reads the first header and the second header to determine which file of the first data block and the second data block is smaller.

In some examples, the computing device 100 determines at least one of the first data block or the second data block includes more than one row of data. Based at least in part on the determination, the computing device 100 determines the smaller file of the first data block and the second data block.

In operation 1107, the computing device 100 finalizes compression of the vertex via the compression method corresponding to the determined smaller file of the first data block and the second data block. In other words, in operation 1107, based on the determined smaller file being the first data block, the computing device 100 finalizes compression of the vertex using the first compression method, i.e., the column-chunk compression method. In operation 1109, based on the determined smaller file being the second data block, the computing device 100 finalizes compression of the vertex using the second compression method, i.e., the row-by-row compression method.

In operation 1111, the computing device 100 transfers the compressed vertex to an external format for long-term storage. For example, a long-term storage location includes, but is not limited to, a data unit, a partition stream, and so forth. In some examples, transferring the compressed vertex to an external format provides gains in both compressed and non-compressed form.

In some examples, the computing device 100 sets the selected compression method as a default compression method for future transfers of the vertex. For example, where the selected compression method is the column-chunk compression method, the computing device 100 sets, i.e., saves, the column-chunk compression method as the default format for transferring the vertex. In some examples, the computing device 100 further sets the column-chunk compression method as the default format for transferring vertices similar to the vertex. A vertex can be determined to be similar based on having a header that includes similar size, number of rows, and so forth as the vertex.

### Additional Examples

Some examples herein are directed to a method of transferring a vertex including data using a hybrid intermediate stream format, as illustrated by the method 1100. The method includes compressing (1101) a vertex into a first data block via a first compression method, compressing (1103) the vertex into a second data block via a second compression method, determining (1105) a smaller file of the first data block and the second data block, finalizing (1107, 1109) compression of the vertex via a compression method, selected from the first compression method and the second compression method, corresponding to the determined smaller file of the first data block and the second data block, and transferring (1111) the compressed vertex.

In some examples, the first data block includes a first header and the second data block includes a second header. The first header is a representation of data contained in the first data block and includes a size of the first data block and a number of rows in the first data bloc. The second header is a representation of data contained in the second data block and includes a size of the second data block and a number of rows in the second data block. The method further includes determining the smaller file of the first data block and the second data block includes reading the first header and the second header.

In some examples, determining the smaller file of the first data block and the second data block includes determining the smaller file is a lower resource cost to compress and transfer than a comparatively larger file.

In some examples, transferring the compressed vertex includes transferring the compressed vertex to a long-term storage location.

In some examples, the method further includes setting the selected compression method as a default compression method.

In some examples, the method further includes determining at least one of the first data block or the second data block includes more than one row of data; and based on least in part on the determination, determining the smaller file of the first data block and the second data block.

Although described in connection with an example computing device 100, examples of the disclosure are capable of implementation with numerous other general-purpose or special-purpose computing system environments, configurations, or devices. Examples of well-known computing systems, environments, and/or configurations that may be suitable for use with aspects of the disclosure include, but are not limited to, smart phones, mobile tablets, mobile computing devices, personal computers, server computers, hand-held or laptop devices, multiprocessor systems, gaming consoles, microprocessor-based systems, set top boxes, programmable consumer electronics, mobile telephones, mobile computing and/or communication devices in wearable or accessory form factors (e.g., watches, glasses, headsets, or earphones), network PCs, minicomputers, mainframe computers, distributed computing environments that include any of the above systems or devices, virtual reality (VR) devices, augmented reality (AR) devices, mixed reality (MR) devices, holographic device, and the like. Such systems or devices may accept input from the user in any way, including from input devices such as a keyboard or pointing device, via gesture input, proximity input (such as by hovering), and/or via voice input.

Examples of the disclosure may be described in the general context of computer-executable instructions, such as program modules, executed by one or more computers or other devices in software, firmware, hardware, or a combination thereof. The computer-executable instructions may be organized into one or more computer-executable components or modules. Generally, program modules include, but are not limited to, routines, programs, objects, components, and data structures that perform particular tasks or implement particular abstract data types. Aspects of the disclosure may be implemented with any number and organization of such components or modules. For example, aspects of the disclosure are not limited to the specific computer-executable instructions or the specific components or modules illustrated in the figures and described herein. Other examples of the disclosure may include different computer-executable instructions or components having more or less functionality than illustrated and described herein. In examples involving a general-purpose computer, aspects of the disclosure transform the general-purpose computer into a special-purpose computing device when configured to execute the instructions described herein.

By way of example and not limitation, computer readable media comprise computer storage media and communication media. Computer storage media include volatile and nonvolatile, removable, and non-removable memory implemented in any method or technology for storage of information such as computer readable instructions, data structures, program modules, or the like. Computer storage media are tangible and mutually exclusive to communication media. Computer storage media are implemented in hardware and exclude carrier waves and propagated signals. Computer storage media for purposes of this disclosure are not signals per se. Exemplary computer storage media include hard disks, flash drives, solid-state memory, phase change random-access memory (PRAM), static random-access memory (SRAM), dynamic random-access memory (DRAM), other types of random-access memory (RAM), read-only memory (ROM), electrically erasable programmable read-only memory (EEPROM), flash memory or other memory technology, compact disk read-only memory (CD-ROM), digital versatile disks (DVD) or other optical storage, magnetic cassettes, magnetic tape, magnetic disk storage or other magnetic storage devices, or any other non-transmission medium that can be used to store information for access by a computing device. In contrast, communication media typically embody computer readable instructions, data structures, program modules, or the like in a modulated data signal such as a carrier wave or other transport mechanism and include any information delivery media.

The order of execution or performance of the operations in examples of the disclosure illustrated and described herein is not essential and may be performed in different sequential manners in various examples. For example, it is contemplated that executing or performing a particular operation before, contemporaneously with, or after another operation is within the scope of aspects of the disclosure. When introducing elements of aspects of the disclosure or the examples thereof, the articles “a,” “an,” “the,” and “said” are intended to mean that there are one or more of the elements. The terms “comprising,” “including,” and “having” are intended to be inclusive and mean that there may be additional elements other than the listed elements. The term “exemplary” is intended to mean “an example of.” The phrase “one or more of the following: A, B, and C” means “at least one of A and/or at least one of B and/or at least one of C.”

Having described aspects of the disclosure in detail, it will be apparent that modifications and variations are possible without departing from the scope of aspects of the disclosure as defined in the appended claims. As various changes could be made in the above constructions, products, and methods without departing from the scope of aspects of the disclosure, it is intended that all matter contained in the above description and shown in the accompanying drawings shall be interpreted as illustrative and not in a limiting sense.

While no personally identifiable information is tracked by aspects of the disclosure, examples have been described with reference to data monitored and/or collected from the users. In some examples, notice may be provided to the users of the collection of the data (e.g., via a dialog box or preference setting) and users are given the opportunity to give or deny consent for the monitoring and/or collection. The consent may take the form of opt-in consent or opt-out consent.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

It will be understood that the benefits and advantages described above may relate to one example or may relate to several examples. The examples are not limited to those that solve any or all of the stated problems or those that have any or all of the stated benefits and advantages. It will further be understood that reference to ‘an’ item refers to one or more of those items.

The term “comprising” is used in this specification to mean including the feature(s) or act(s) followed thereafter, without excluding the presence of one or more additional features or acts.

In some examples, the operations illustrated in the figures may be implemented as software instructions encoded on a computer readable medium, in hardware programmed or designed to perform the operations, or both. For example, aspects of the disclosure may be implemented as a system on a chip or other circuitry including a plurality of interconnected, electrically conductive elements.

The order of execution or performance of the operations in examples of the disclosure illustrated and described herein is not essential, unless otherwise specified. That is, the operations may be performed in any order, unless otherwise specified, and examples of the disclosure may include additional or fewer operations than those disclosed herein. For example, it is contemplated that executing or performing a particular operation before, contemporaneously with, or after another operation is within the scope of aspects of the disclosure.

What is claimed is:

1. A computer-implemented method, the method comprising:
compressing a vertex into a first data block via a first compression method;
compressing the vertex into a second data block via a second compression method;
determining a smaller file of the first data block and the second data block;
finalizing compression of the vertex via a compression method, selected from the first compression method and the second compression method, corresponding to the determined smaller file of the first data block and the second data block; and
transferring the compressed vertex.

2. The computer-implemented method of claim 1, wherein:
the first data block includes a first header,
the second data block includes a second header, and
determining the smaller file of the first data block and the second data block includes reading the first header and the second header.

3. The computer-implemented method of claim 2, wherein:
the first header is a representation of data contained in the first data block, and
the second header is a representation of data contained in the second data block.

4. The computer-implemented method of claim 2, wherein:
the first header includes a size of the first data block and a number of rows in the first data block, and
the second header includes a size of the second data block and a number of rows in the second data block.

5. The computer-implemented method of claim 1, wherein determining the smaller file of the first data block and the second data block includes determining the smaller file is a lower resource cost to compress and transfer than a comparatively larger file.

6. The computer-implemented method of claim 1, wherein transferring the compressed vertex includes transferring the compressed vertex to a long-term storage location.

7. The computer-implemented method of claim 1, further comprising setting the selected compression method as a default compression method.

8. The computer-implemented method of claim 1, further comprising:
determining at least one of the first data block or the second data block includes more than one row of data; and
based on least in part on the determination, determining the smaller file of the first data block and the second data block.

9. One or more servers, each of the one or more servers comprising:
a processor; and
a computer-readable medium storing instructions that, when executed by the processor, cause the processor to:
compress a vertex into a first data block via a first compression method, the first data block including a first header;
compress the vertex into a second data block via a second compression method, the second data block including a second header;
read the first header and the second header;
based at least in part on the reading of the first header and the second header, determine a smaller file of the first data block and the second data block;
finalize compression of the vertex via a compression method, selected from the first compression method and the second compression method, corresponding to the determined smaller file of the first data block and the second data block; and
transfer the compressed vertex.

10. The one or more servers of claim 9, wherein:
the first header is a representation of data contained in the first data block, and
the second header is a representation of data contained in the second data block.

11. The one or more servers of claim 9, wherein:
the first header includes a size of the first data block and a number of rows in the first data block, and
the second header includes a size of the second data block and a number of rows in the second data block.

12. The one or more servers of claim 9, wherein the computer-readable medium further stores instructions that, when executed by the processor, causes the processor to, to determine the smaller file of the first data block and the second data block, determine the smaller file is a lower resource cost to compress and transfer than a comparatively larger file.

13. The one or more servers of claim 9, wherein the computer-readable medium further stores instructions that, when executed by the processor, causes the processor to, to transfer the compressed vertex, transfer the compressed vertex to a long-term storage location.

14. The one or more servers of claim 9, wherein the computer-readable medium further stores instructions that, when executed by the processor, causes the processor to set the selected compression method as a default compression method.

15. The one or more servers of claim 9, wherein the computer-readable medium further stores instructions that, when executed by the processor, causes the processor to:
determine at least one of the first data block or the second data block includes more than one row of data; and
based on least in part on the determination, determine the smaller file of the first data block and the second data block.

16. One or more computer-storage memory devices embodied with executable operations that, when executed by a processor, cause the processor to:
compress a vertex into a first data block via a first compression method;
compress the vertex into a second data block via a second compression method;
determine a smaller file of the first data block and the second data block;
finalize compression of the vertex via a compression method, selected from the first compression method and the second compression method, corresponding to the determined smaller file of the first data block and the second data block; and
transfer the compressed vertex.

17. The one or more computer-storage memory devices of claim 16, wherein:
the first data block includes a first header that is a representation of data contained in the first data block, the first header including a size of the first data block and a number of rows in the first data block,
the second data block includes a second header that is a representation of data contained in the second data block, the second header including a size of the second data block and a number of rows in the second data block,
the one or more computer-storage memory devices are further embodied with executable operations that, when executed by a processor, cause the processor to:
to determine the smaller file of the first data block and the second data block, read the first header and the second header

18. The one or more computer-storage memory devices of claim 16, wherein the one or more computer-storage memory devices are further embodied with executable operations that, when executed by a processor, cause the processor to:
to determine the smaller file of the first data block and the second data block, determine the smaller file is a lower resource cost to compress and transfer than a comparatively larger file.

19. The one or more computer-storage memory devices of claim 16, wherein the one or more computer-storage memory devices are further embodied with executable operations that, when executed by a processor, cause the processor to:
set the selected compression method as a default compression method.

20. The one or more computer-storage memory devices of claim 16, wherein the one or more computer-storage memory devices are further embodied with executable operations that, when executed by a processor, cause the processor to:
determine at least one of the first data block or the second data block includes more than one row of data; and
based on least in part on the determination, determine the smaller file of the first data block and the second data block.
